(19) United States
(12) Patent Application Publication
(10) Pub. No.: US 2021/0235586 A1
(43) Pub. Date: Jul. 29, 2021

(54) ELECTRICAL DEVICE HAVING JUMPER

(71) Applicant: 3M INNOVATIVE PROPERTIES COMPANY, St. Paul, MN (US)

(72) Inventors: Teresa M. Goeddel, St. Paul, MN (US); Ankit Mahajan, Cupertino, CA (US); Mikhail L. Pekurovsky, Bloomington, MN (US); Thomas J. Metzler, St. Paul, MN (US); Saagar A. Shah, Minneapolis, MN (US); Kara A. Meyers, Oakdale, MN (US); Jonathan W. Kemling, Woodbury, MN (US); Jeremy K. Larsen, Farmington, MN (US)

(21) Appl. No.: 16/948,657

(22) PCT Filed: Mar. 27, 2019
(86) PCT No.: PCT/IB2019/052491

§ 371 Date: Sep. 28, 2020

Related U.S. Application Data
(60) Provisional application No. 62/651,432, filed on Apr. 2, 2018.

(51) Int. Cl. H05K 3/12; H05K 1/09

(52) U.S. Cl. CPC H05K 3/1258; H05K 3/1283; H05K 1/097

(57) ABSTRACT

Processes of making an electrical jumper (120) for electrical devices are provided. A micro-replication stamp (300) is used to press a layer of curable material (124) on a circuit substrate (102) to make patterned features. A conductive liquid (230) is disposed into the patterned features to make electrically conductive traces (126) that pass over a circuitry (110) and connect electrical contacts (122A, 122B). In some cases, the stamp (300) has a standoff (310).

### TECHNICAL FIELD

The present disclosure relates to electrical devices having a jumper passing over an electrical circuitry and electrically connecting electrical contacts, and methods of making and using the same.

### BACKGROUND

Jumpers are widely used in electrical devices. One traditional way is to use an insulated cable that passes over the top of an electrical circuitry, while electrically insulated from the underneath electrical circuitry. Then, the exposed ends of the cable are soldered to electrical contacts of the device. This creates a “bridge” phenomenon, where the cable connects the two ends of the antenna, but does not connect to any other portion to avoid shorting. Other players in industry have attempted to print the dielectric layer, then print silver on top of it, but industry standard practice seems to be a two-layer printed layer.

### SUMMARY

There is a desire to optimize jumpers for electrical devices and make the jumpers in a simple and cost-effective way. Briefly, in one aspect, the present disclosure describes an electrical device including a substrate having a major surface. An electrical circuitry is provided on the major surface of the substrate. The electrical circuitry includes first and second electrical contacts separated by a portion of the electrical circuitry. An electrical jumper passes over at least a portion of the electrical circuitry and electrically connects the first and second electrical contacts. The electrical jumper includes an insulating layer disposed on the major surface of the substrate and covering at least a portion of the electrical circuitry. At least one channel is formed onto the insulating layer, and an electrically conductive trace is formed in the channel to electrically connect the first and second electrical contacts, while electrically isolated from the underneath electrical circuitry.

In another aspect, the present disclosure describes a method of making an electrical device. The method includes providing a substrate having a major surface, where an electrical circuitry is provided on the major surface of the substrate. The electrical circuitry includes first and second electrical contacts separated by a portion of the electrical circuitry. The method further includes providing a layer of curable material to cover at least a portion of the electrical circuitry on the major surface of the substrate; pressing a micro-replication stamp against the layer of curable material to create pattern features thereon; curing the curable material to form an insulating layer having at least one channel thereon; and disposing a conductive liquid into the channel to form a conductive trace connecting to the first and second electrical contacts of the electrical circuitry. In some embodiments, the method further includes solidifying the conductive liquid to form an electrically conductive trace in the channel to electrically connect the first and second electrical contacts, while electrically isolated from the underneath electrical circuitry.

Various unexpected results and advantages are obtained in exemplary embodiments of the disclosure. One such advantage of exemplary embodiments of the present disclosure is that the jumpers described herein are optimized to have a single-layer structure, without compromising its superior electrical and mechanical properties.

Various aspects and advantages of exemplary embodiments of the disclosure have been summarized. The above Summary is not intended to describe each illustrated embodiment or every implementation of the present certain exemplary embodiments of the present disclosure. The Drawings and the Detailed Description that follow more particularly exemplify certain preferred embodiments using the principles disclosed herein.

### BRIEF DESCRIPTION OF THE DRAWINGS

The disclosure may be more completely understood in consideration of the following detailed description of various embodiments of the disclosure in connection with the accompanying figures, in which:

FIG. 1A is a top view of an electrical device including a jumper, according to one embodiment.

FIG. 1B is a cross-sectional view of the electrical device of FIG. 1A along the line 1B-1B.

FIG. 1C is a top view of an electrical device including a jumper, according to another embodiment.

FIG. 1D is a cross-sectional view of the electrical device of FIG. 1C along the line 1D-1D.

FIG. 2A is a cross-sectional view of an electrical device having a layer of curable material thereon, according to one embodiment.

FIG. 2B illustrates a process of pressing a micro-replication stamp against the layer of curable material of FIG. 2A.

FIG. 2C illustrates a process of curing the curable material of FIG. 2B.

FIG. 2D is a cross-sectional view of an insulating layer obtained by the process of FIG. 2C.

FIG. 2E illustrates a process of disposing a conductive liquid into the channel of the insulating layer of FIG. 2D.

FIG. 2F is a cross-sectional view of a jumper obtained by solidifying the conductive liquid of FIG. 2E.

FIG. 3A is a top view of a micro-replication stamp including a standoff, according to one embodiment.

FIG. 3B is a cross-sectional view of the stamp of FIG. 3A along the line 3B-3B.

FIG. 3C is a cross-sectional view of the stamp of FIG. 3A along the line 3C-3C.

FIG. 3D is a cross-sectional view of the stamp of FIG. 3A along the line 3D-3D.

FIG. 3E is a cross-sectional view of the stamp of FIG. 3A along the line 3E-3E.

In the drawings, like reference numerals indicate like elements. While the above-identified drawing, which may not be drawn to scale, sets forth various embodiments of the present disclosure, other embodiments are also contemplated, as noted in the Detailed Description. In all cases, this disclosure describes the presently disclosed disclosure by way of representation of exemplary embodiments and not by express limitations. It should be understood that numerous other modifications and embodiments can be devised by those skilled in the art, which fall within the scope and spirit of this disclosure.

### DETAILED DESCRIPTION

For the following Glossary of defined terms, these definitions shall be applied for the entire application, unless a different definition is provided in the claims or elsewhere in the specification.

### Glossary

Certain terms are used throughout the description and the claims that, while for the most part are well known, may require some explanation. It should be understood that:

The term “curable material” refers to a material that is viscous when uncured, and solidifies when exposed to heat, UV, or another energy source. The curable material can adhere to the underlying substrate after curing, and be electrically insulating to the underlying circuitry.

The term “conductive liquid” refers to a liquid composition that is flowable in a channel via capillary. The conductive liquid described herein can be solidified to form electrically conductive traces. The conductive liquid may include any suitable electronic material having properties desired for use in forming electrically conductive traces.

The term “adjoining” with reference to a particular layer means joined with or attached to another layer, in a position wherein the two layers are either next to (i.e., adjacent to) and directly contacting each other, or contiguous with each other but not in direct contact (i.e., there are one or more additional layers intervening between the layers).

By using terms of orientation such as “atop”, “on”, “over,” “bottom,” “up,” “covering”, “uppermost”, “underlying” and the like for the location of various elements in the disclosed coated articles, we refer to the relative position of an element with respect to a horizontally-disposed, upwardly-facing substrate. However, unless otherwise indicated, it is not intended that the substrate or articles should have any particular orientation in space during or after manufacture.

The terms “about” or “approximately” with reference to a numerical value or a shape means+/−five percent of the numerical value or property or characteristic, but expressly includes the exact numerical value. For example, a viscosity of “about” 1 Pa-sec refers to a viscosity from 0.95 to 1.05 Pa-sec, but also expressly includes a viscosity of exactly 1 Pa-sec. Similarly, a perimeter that is “substantially square” is intended to describe a geometric shape having four lateral edges in which each lateral edge has a length which is from 95% to 105% of the length of any other lateral edge, but which also includes a geometric shape in which each lateral edge has exactly the same length.

The term “substantially” with reference to a property or characteristic means that the property or characteristic is exhibited to a greater extent than the opposite of that property or characteristic is exhibited. For example, a substrate that is “substantially” transparent refers to a substrate that transmits more radiation (e.g. visible light) than it fails to transmit (e.g. absorbs and reflects). Thus, a substrate that transmits more than 50% of the visible light incident upon its surface is substantially transparent, but a substrate that transmits 50% or less of the visible light incident upon its surface is not substantially transparent.

As used in this specification and the appended embodiments, the singular forms “a”, “an”, and “the” include plural referents unless the content clearly dictates otherwise. Thus, for example, reference to fine fibers containing “a compound” includes a mixture of two or more compounds. As used in this specification and the appended embodiments, the term “or” is generally employed in its sense including “and/or” unless the content clearly dictates otherwise.

As used in this specification, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

Various exemplary embodiments of the disclosure will now be described with particular reference to the Drawings. Exemplary embodiments of the present disclosure may take on various modifications and alterations without departing from the spirit and scope of the disclosure. Accordingly, it is to be understood that the embodiments of the present disclosure are not to be limited to the following described exemplary embodiments, but are to be controlled by the limitations set forth in the claims and any equivalents thereof.

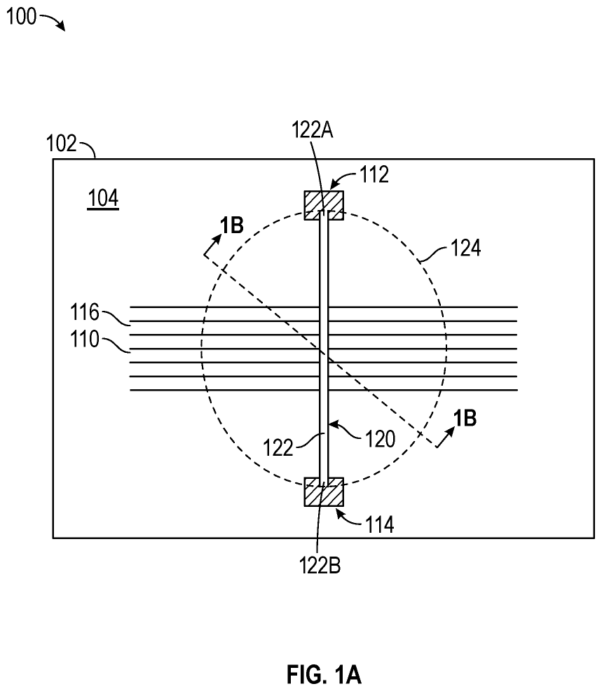

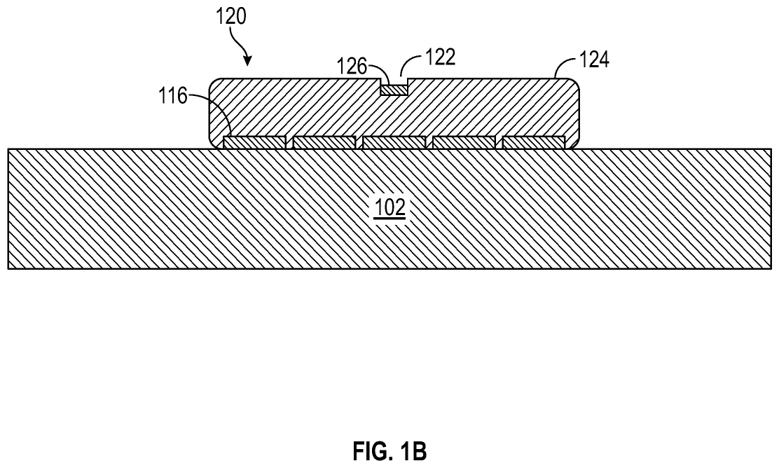

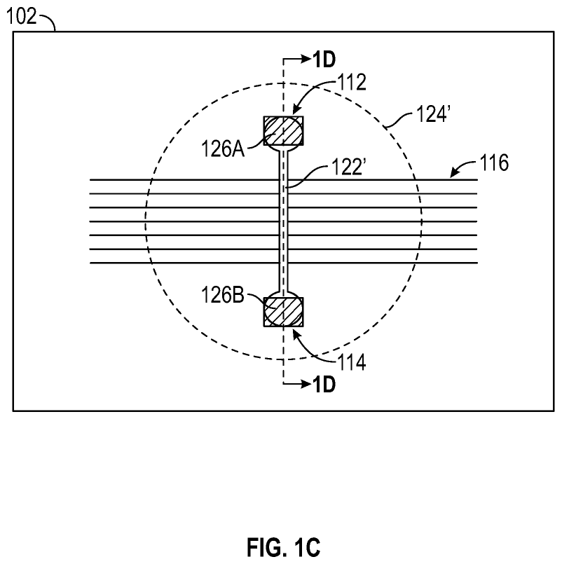

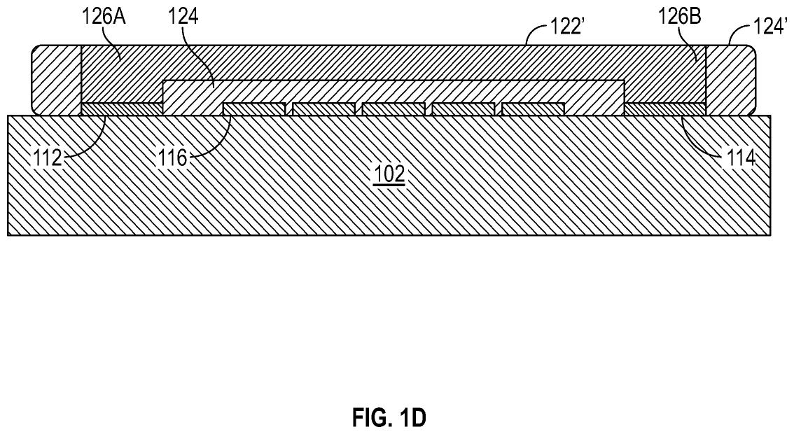

FIG. 1A is a top view of an electrical device 100 including a jumper, according to one embodiment. The electrical device 100 includes a substrate 102 having a major surface 104. An electrical circuitry 110 is formed on the major surface 104 of the substrate 102. The electrical circuitry 110 includes conductive traces 116, and first and second electrical contacts 112 and 114 separated by the conductive traces 116. The first and second electrical contacts may have the respective electrical traces (not shown) connected to the electrical circuitry 110. In some embodiments, the electrical circuitry 110 may be a printed circuit board (PCB) that mechanically supports and electrically connects electronic components. Conductive tracks, pads and other features can be formed by etching from one or more sheet layers of conductive materials (e.g., copper) laminated onto and/or between sheet layers of a non-conductive substrate. In some embodiments, the electrical circuitry 110 may be a flex circuit and the substrate 102 can be a flexible plastic substrate such as, for example, polyimide, polyester, etc. Flex circuits can be screen printed on the flexible plastic substrate to form the electrical circuitry 110. In some embodiments, the electrical contacts or conducive traces on the substrate each may be covered by a layer of polymeric material (e.g., a resist layer). It is to be understood that the electrical circuitry 110 can be any suitable circuitry other than a PCB or a flex circuit.

In some embodiments, the electrical circuitry 110 may include an antenna assembly including multiple antennas electrically connected, and the first and second electrical contacts 112 and 114 may be located at the respective ends of the adjacent antennas. In some embodiments, one or more jumpers can be provided to electrically connect the electrical contacts of the adjacent antennas. In some embodiments, for a high-frequency (HF) antenna construction, the inside and part of the coil antenna can be connected to the outside part of the coil antenna via a jumper to complete the construction of the single antenna. The outside part of the antenna can then be connected to adjacent antennas to form an assembly of antennas.

Referring to FIGS. 1A-B, an electrical jumper 120 is provided to pass over at least a portion of the electrical circuitry 110 (e.g., the conductive traces 116) and electrically connecting the first and second electrical contacts 112 and 114. The electrical jumper 120 includes an insulating layer 124 disposed on the major surface 104 of the substrate 102 and covering at least a portion of the electrical circuitry 110. As shown in FIGS. 1A-B, at least one channel 122 is formed onto an upper surface of the insulating layer 124 opposite to the conductive traces 116 on the substrate 102. The channel 122 extends between first and second ends 122A and 122B. An electrically conductive trace 126 is formed in the channel 122 to electrically connect the first and second electrical contacts 112 and 114. The electrically conductive trace 126 is electrically isolated, via the insulating layer 124, from the underneath electrical circuitry (e.g., the conductive traces 116 of the electrical circuitry 110). In some embodiments, the insulating layer 124 can be a curing product of a curable material. The curable material may include, for example, an adhesive, an acrylate, a urethane, an epoxy, etc.

The insulating layer 124 may have a thickness, for example, from about 10 microns to about 5.0 mm, or from about 50 microns to about 1.0 mm. The channel 122 may have a depth, for example, from about 5 microns to about 1.0 mm, or from about 10 microns to about 2.0 mm. In general, the insulating layer 124 has a thickness greater than the sum of the depth of the channel and the height of the conductive traces 116 to avoid undesired electrical shorting.

In some embodiments, the electrically conductive trace 126 in the channel 122 may connect to the underlying electrical contacts 112 and 114 at the respective open ends 122A and 122B as shown in FIG. 1A. The electrically conductive trace 126 can extend continuously toward the electrical contacts 112 and 114 to form the electrical connection therebetween. In some embodiments, the electrically conductive trace 126 can be soldered to the electrical contacts 112 and 114 at the respective open ends 122A and 122B.

In some embodiments, the insulating layer may further include one or more reservoirs to access to the underneath electrical contacts (e.g., the contacts 112 and/or 114 in FIG. 1A). In the depicted embodiment of FIGS. 1C-D, the insulating layer 124′ includes first and second reservoirs 126A and 126B, and a channel 122′ fluidly connects the first and second reservoirs 126A and 126B. The first and second reservoirs 126A and 126B are through holes that extend through the insulating layer 124′ and access to the respective electrical contacts 112 and 114 on the substrate 102.

As shown in FIG. 1D, when an electrically conductive trace is formed in the channel 122′ and the reservoirs 126A and 126B, the electrically conductive trace can electrically connect to the first and second electrical contacts 112 and 114 via the reservoirs 126A and 126B, while the electrically conductive trace in the channel 122′ is electrically insulated, via the insulating layer 124′, from the underneath conductive traces 116 on the substrate 102.

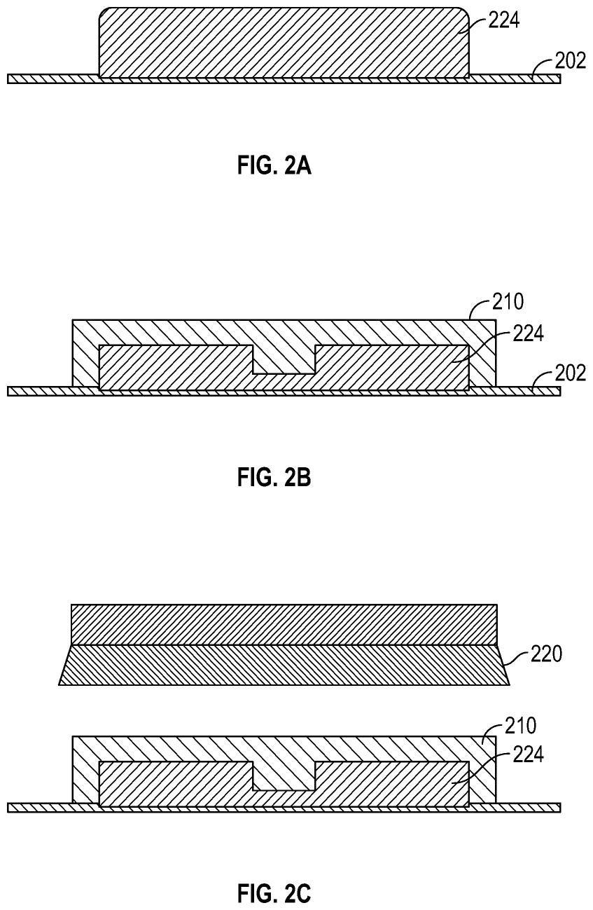

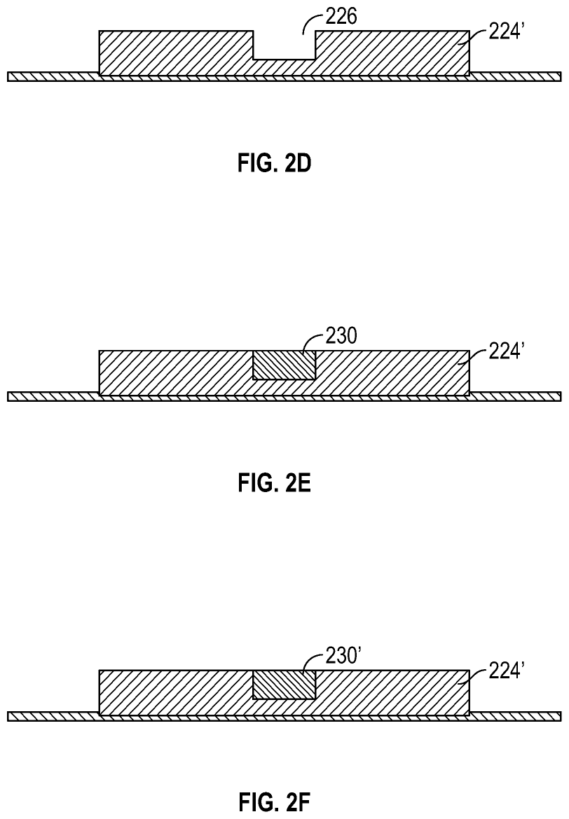

FIGS. 2A-2F illustrate a process of making an electrical device including a jumper, according to one embodiment. As shown in FIG. 2A, a layer of curable material 224 is provided to cover at least a portion of an electrical circuitry on the major surface of the substrate 202. The substrate 202 can be the substrate 102 in FIGS. 1A-C. The substrate 202 has a major surface and an electrical circuitry is provided on the major surface of the substrate. The electrical circuitry includes first and second electrical contacts separated by a portion of the electrical circuitry. In some embodiments, the curable material may include, for example, an adhesive, an acrylate, a urethane, an epoxy, etc. It is to be understood that any suitable curable material can be used, including, for example, structural adhesive, pressure-sensitive adhesive (PSA), epoxy, other types of resins, etc. The layer of adhesive 224 may be applied as an adhesive fluid to cover a localized area on the substrate with any of several convenient coating techniques such as, for example, printing/dispensing such as flexo, inkjet printing, pico-pulse printing, needle printing, micro-pipette printing, etc.

As shown in FIG. 2B, a micro-replication stamp 210 is provided to press against the layer of curable material 224 to create pattern features thereon. The pattern features may include, for example, one or more channels such as the channel 122 in FIGS. 1A-B, one or more reservoirs such as the reservoirs 126A and 126B in FIGS. 1C-D, etc. Then, the curable material is cured by a solidifying unit 220 to form an insulating layer 224′ having at least one channel 226 thereon, as shown in FIG. 2D. In some convenient embodiments, the fluid can be cured with, e.g., thermal, UV or e-beam radiation. In other convenient embodiments, the fluid can be dried through solvent evaporation through active or passive drying. In the depicted embodiment of FIG. 2C, the solidifying unit 220 is a UV LED unit that is used to cure the adhesive layer 224 with the micro-replication stamp 210 still in place. It is to be understood that any suitable solidifying methods can be used to solidify the fluid layer 224 to form the insulating layer 224′.

After the solidification of the fluid layer 224, the stamp 210 is removed to reveal the pattern features (e.g., channels, reservoirs, etc.) formed onto the upper surface of the insulating layer 224′. After the formation of the channel 226, a conductive liquid 230 is disposed into the channel 226, as shown in FIG. 2E. The channel 226 is configured to allow fluid to flow primarily via a capillary force, for example, from the one end toward the other end. In some embodiments, at least one of the channels or at least a portion of one channel may be open on the upper surface. In some embodiments, at least one of the channels or at least a portion of one channel may be enclosed by an upper wall. The conductive liquid 230 can be a liquid composition that is flowable in the channels 226 primarily by a capillary force. The conductive liquid may include, for example, a liquid carrier and one or more electronic material, a liquid metal or metal alloy, etc. The conductive liquid described herein can be solidified to leave a continuous layer of electrically conductive material that forms an electrically conductive trace in one or more channels and/or reservoirs. Suitable liquid compositions may include, for example, silver ink, silver nanoparticle ink, reactive silver ink, copper ink, conductive polymer inks, liquid metals or alloys (e.g., metals or alloys that melt at low temperatures and solidify at room temperatures), etc. One example of silver ink is commercially available from NovaCentrix (Austin, Tex., USA) under the trade designation PSPI-1000 Conductive Spray Ink. The conductive liquid can be disposed by, for example, ink jet printing, dispensing such as piezo dispensing, needle dispensing, screen printing, flexo printing, etc.

In some embodiments, when the conductive liquid is delivered into an end of the channel, the conductive liquid can be routed, by virtue of a capillary pressure, through the channel from one end toward another end of the channel, and to make direct contact with electrical contacts on the substrate (e.g., the first and second electrical contacts 112 and 114 of the electrical circuitry 110 as shown in FIG. 1A).

While not wanting to be bounded by theory, it is believed that a number of factors can affect the ability of the conductive liquid to move through the channel via capillarity. Such factors may include, for example, the dimensions of the channels, the viscosity of the conductive liquid, surface energy, surface tension, drying, etc. The factors were discussed in U.S. Pat. No. 9,401,306 (Mahajan et al.), which is incorporated herein by reference. The channels described herein can have any suitable dimensions (e.g., width, depth, or length) which can, in part, be determined by one or more of the factors described above. In some embodiments, the channel may have a width or depth in a range, for example, from about 0.1 microns to about 1 mm, from about 0.5 microns to about 500 microns, or from about one micron to about 200 microns.

When the channel connects first and second reservoirs (e.g., the reservoirs 126A and 126B in FIGS. 1C-D), the conductive liquid can flow into the reservoirs and make direct contact with the respective underneath electrical contacts (e.g., the first and second electrical contacts 112 and 114). In some embodiments, the conductive liquid can be disposed into one or more reservoirs and the conductive liquid can be routed, by virtue of a capillary pressure, into the connected channel(s) and reservoir(s). In some embodiments, the conductive liquid can be dispensed simultaneously into both reservoirs and the conductive trace in the channel can be completed by merging the two advancing liquid fronts somewhere close to the middle of the channel. In some embodiments, two or more channels can be provided to connect the respective reservoirs to increase the current carrying capacity of the conductive trace.

While not wanting to be bounded by theory, it is believed that dispensing of the conductive fluid into a reservoir can perform two functions including: (i) connecting to the conductive traces on the underlying electrical contacts on the substrate; and (ii) initiating capillary flow of the conductive liquid from one reservoir to the other, thereby forming a conductive trace in the channel to connect the underling electrical contacts. In traditional jumper manufacturing processes, a dielectric layer has to be printed multiple times to prevent formation of holes in the dielectric layer. This leads to a high thickness of the dielectric layer. The corresponding conductive traces printed on the dielectric layer has to increase its thickness to account for the step height from the dielectric layer, which results in a relatively thick jumper structure. The processes described in the present disclosure can effectively overcome such problems in the traditional processes.

After the conductive liquid 230 makes direct contact to the electrical contacts of the circuitry, the conductive liquid can be solidified to form an electrically conductive trace 230′ as shown in FIG. 2F. Suitable processes that can be used to enhance the solidification of the conductive liquid 16 may include, for example, curing or evaporating by heat or radiation. The electrically conductive trace in the channel and/or reservoir electrically connects the electrical contacts, while being electrically isolated from the underneath electrical circuitry.

The exemplary process illustrated in FIGS. 2A-2F can make an electrical jumper having a single-layer structure on the substrate. It can eliminate the necessity of adding an intermediate insulating layer between the jumper and the underneath electrical circuitry to prevent undesired electrical shorting.

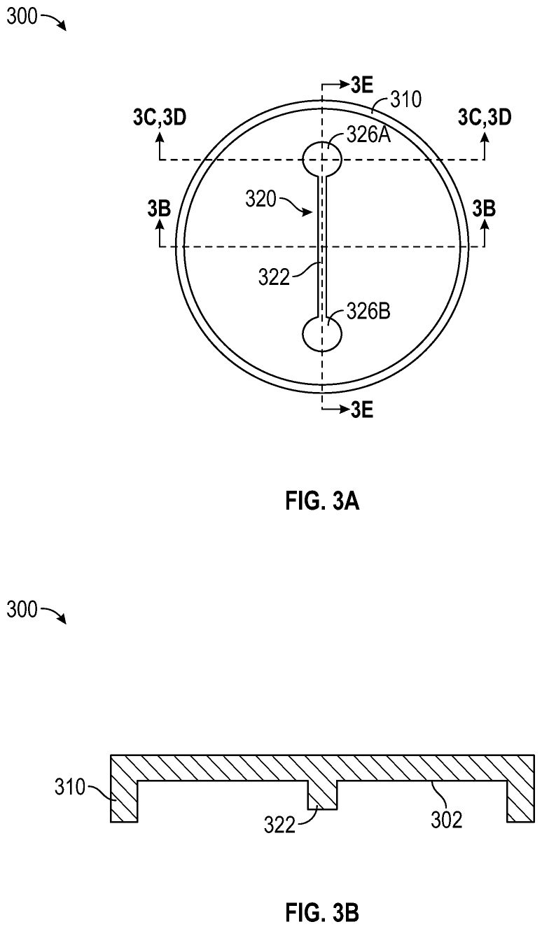

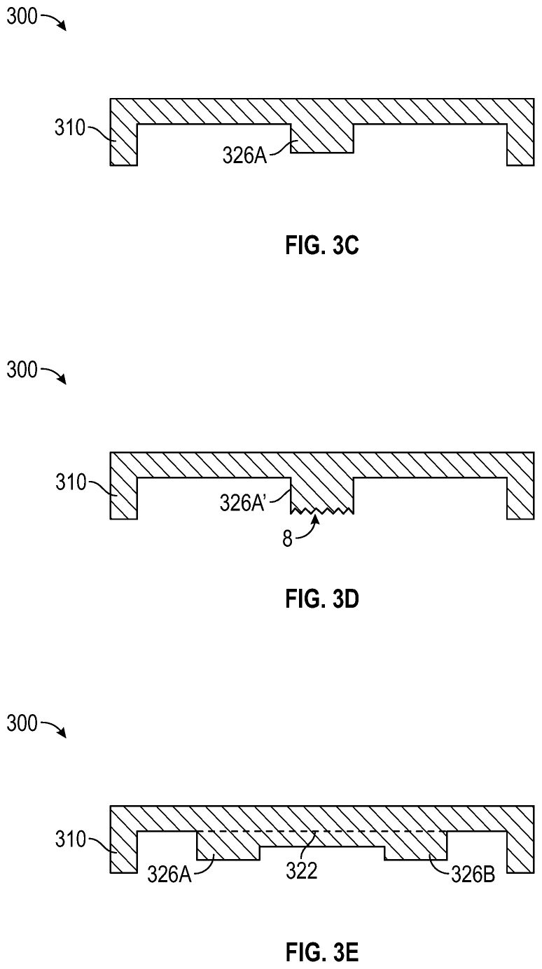

FIGS. 3A-E illustrate a micro-replication stamp 300 described herein that is used to make patterned features on an insulating layer such as in the exemplary process of FIGS. 2B-C. The stamp 300 includes one or more micro-replicated features formed on a major surface 302 thereof. In the depicted embodiment, the micro-replicated features 320 include first and second reservoir features 326A and 326B in negative relief connected by the at least one channel feature 322 in negative relief. A standoff 310 projects from the major surface 302 thereof. The standoff 310 is located around a periphery of the stamp 300, at least partially surrounding the micro-replicated features (e.g., the channel feature 322, the reservoir features 326A and 326B, etc.).

In some embodiments, the standoff 310 can have a height no less than that of the micro-replicated features (e.g., the reservoir features 326A and 326B, or the channel feature 322). For example, the standoff 310 may have a height about one time, 1.2 times, 1.5 times, or 2 times of the micro-replicated features. When the stamp is pressed against a substrate such as shown in FIG. 2B, the pressure can be uniformly distributed along the standoff 310. This can help to achieve a precise contact between the micro-replicated features of the stamp and the curable insulating layer on the substrate. In some cases, the use of a suitable standoff can avoid a poor bottom surface in the created channel(s) and undesired electrical shorting when a conductive trace is formed in the channel(s).

In some embodiments, when the stamp is pressed against a substrate having a layer of curable material disposed thereon (e.g., 224 in FIG. 2A), the standoff thereof may at least partially fall on the curable material and leave its footprint thereon. The footprint may be a recess having a shape of the standoff in negative relief. A residual layer of curable material may retain at the bottom surface of the footprint. In some embodiments, the footprint of the standoff may at least partially surround the pattern features (e.g., channels, reservoirs, etc.) formed on the insulating layer. The footprint may have a round shape, an oval shape, a rectangular shape, an arc shape, etc.

In some embodiments, the reservoir feature in negative relief can have a height greater than that of the at least one channel feature in negative relief. In the depicted embodiment of FIG. 3E, the first and second reservoir features 326A and 326B each have a height greater than that of the channel feature 322. In some embodiments, the reservoir feature may have a height substantially the same as the thickness of a curable insulating layer and can create through holes to access to the conductive traces on the substrate. In some embodiments, the channel feature may have a height, for example, about 80% to about 20% of the thickness of the curable insulating layer.

In some embodiments, the reservoir feature may have a height slightly lower than the thickness of a curable insulating layer. After a reservoir is created onto the insulating layer, the remaining material on the bottom surface of the reservoir can be removed by, for example, mechanical drilling, laser drilling, reactive ion etching, or any other suitable techniques, to at least partially expose the underneath electrical contacts on the substrate (e.g., 112 and 114 in FIG. 1D). In one embodiment shown in FIG. 3D, the reservoir feature 326A′ has a bottom surface with micro-replicated features 8 formed thereon. The micro-replicated features 8 include sharp micro-replicated peaks and valleys which can induce pinholes in the replicated material. This enables an access to the underlying electrical contacts without a subsequent etching process, and thus can help to form electrical connections between the conductive channel and the underlying electrical contacts (e.g., 112 and 114 in FIG. 1D).

The stamps described herein may be made of a compressible material. In one embodiment, the stamps may include polydimethylsiloxane (PDMS) on its major surface 302. In one example prepared in the present application, a stamp was made of polydimethylsiloxane (PDMS), made using a silicone elastomer kit commercially available from Dow Corning, Midland, Mich., under the trade designation Sylgard 184 PDMS. PDMS stamps can be formed, for example, by dispensing an un-crosslinked PDMS polymer into or against a patterned mold followed by curing. It is to be understood that the stamps can be made of any suitable materials such as, for example, silicone, glass, transparent ceramic, transparent polymer, etc. In some embodiments, the stamps can be transparent to allow UV curing of the underlying curable material. In some embodiments, the stamps may be opaque, and the underlying curable material can be thermally cured. In some embodiments, the curable material can be cured from the side of electrical circuitry.

In one example prepared in the present application, the curable material was a layer of optical adhesive commercially available from Norland Products, Inc. (CRANBURY, N.J., USA) under the trade designation NOA-73. It is to be understood that the stamp can be made of any suitable materials as long as its major surface can be separable from the insulating layer without significantly damaging the patterned features thereon.

The operation of the present disclosure will be further described with regard to the following embodiments. These embodiments are offered to further illustrate the various specific and preferred embodiments and techniques. It should be understood, however, that many variations and modifications may be made while remaining within the scope of the present disclosure.

### Listing of Exemplary Embodiments

It is to be understood that any one of embodiments 1-7, 8-12 and 13-26 can be combined.
Embodiment 1 is an electrical device comprising:

a substrate having a major surface;

an electrical circuitry provided on the major surface of the substrate, the electrical circuitry comprising first and second electrical contacts separated by a portion of the electrical circuitry; and

an electrical jumper passing over at least a portion of the electrical circuitry and electrically connecting the first and second electrical contacts, wherein the electrical jumper comprises an insulating layer disposed on the major surface of the substrate and covering at least a portion of the electrical circuitry, at least one channel is formed onto the insulating layer, and an electrically conductive trace is formed in the channel to electrically connect the first and second electrical contacts, while electrically isolated from the underneath electrical circuitry.

Embodiment 2 is the electrical device of embodiment 1, wherein the insulating layer is a product of curing a curable liquid.
Embodiment 3 is the electrical device of embodiment 1 or 2, wherein the insulating layer has a thickness from about 50 microns to about 2.0 mm, and the at least one channel has a depth from about 10 microns to about 1.0 mm.
Embodiment 4 is the electrical device of any one of embodiments 1-3, wherein the insulating layer further comprises first and second reservoirs, and the at least one channel fluidly connects the first and second reservoirs.
Embodiment 5 is the electrical device of any one of embodiments 1-4, wherein the first and second reservoirs are through holes such that the electrically conductive trace electrically connects to the first and second electrical contacts at the first and second reservoirs, respectively.
Embodiment 6 is the electrical device of any one of embodiments 1-5, wherein the insulating layer has a single layer structure.
Embodiment 7 is the electrical device of any one of embodiments 1-6, wherein the electrical circuitry includes an antenna.
Embodiment 8 is a micro-replication stamp comprising:

one or more micro-replicated features formed on a major surface thereof; and

a standoff projecting from the major surface thereof, the standoff being located at least partially around a periphery of the stamp, wherein the standoff has a height no less than that of the micro-replicated features.

Embodiment 9 is the stamp of embodiment 8, wherein the micro-replicated features include at least one channel feature in negative relief.
Embodiment 10 is the stamp of embodiment 9, wherein the micro-replicated features further include first and second reservoir features in negative relief connected by the at least one channel feature in negative relief.
Embodiment 11 is the stamp of embodiment 10, wherein the first and second reservoir features in negative relief each have a height greater than that of the at least one channel feature in negative relief.
Embodiment 12 is the stamp of any one of embodiments 9-11, wherein the major surface thereof includes one or more compressible material including PDMS.
Embodiment 13 is a method of making an electrical device comprising:

providing a substrate having a major surface, an electrical circuitry provided on the major surface of the substrate, the electrical circuitry comprising first and second electrical contacts separated by a portion of the electrical circuitry;

providing a layer of curable material to cover at least a portion of the electrical circuitry on the major surface of the substrate;

pressing a micro-replication stamp against the layer of curable material to create one or more patterned features thereon;

curing the curable material to form an insulating layer having at least one channel thereon; and

disposing a conductive liquid into the channel to form a conductive trace connecting to the first and second electrical contacts of the electrical circuitry.
Embodiment 14 is the method of embodiment 13, wherein the stamp has micro-replicated features on a major surface thereof to be in contact with the layer of curable material.
Embodiment 15 is the method of embodiment 14, wherein the stamp has a standoff projecting from the major surface thereof, the standoff is located at least partially around a periphery of the stamp.
Embodiment 16 is the method of embodiment 15, wherein the standoff has a height no less than that of the micro-replicated features.
Embodiment 17 is the method of any one of embodiments 13-16, wherein the patterned features include first and second reservoirs and at least one channel fluidly connecting the first and second reservoirs.
Embodiment 18 is the method of embodiment 17, further comprising etching the first and second reservoirs to form through holes to access to the underlying first and second electrical contacts, respectively.
Embodiment 19 is the method of any one of embodiments 13-18, wherein the stamp includes one or more compressible material including PDMS.
Embodiment 20 is the method of any one of embodiments 13-19, wherein the insulating layer has a thickness from about 50 microns to about 2.0 mm, and the at least one channel has a depth from about 10 microns to about 1.0 mm.
Embodiment 21 is the method of any one of embodiments 13-20, wherein the curable material includes an adhesive.
Embodiment 22 is the method of any one of embodiments 13-21, wherein the curable material is cured with the stamp in place.
Embodiment 23 is the method of any one of embodiments 13-22, wherein the conductive liquid includes an ink composition containing electrically conductive particles.
Embodiment 24 is the method of any one of embodiments 13-23, wherein disposing the conductive liquid into the channel comprises flowing the conductive liquid, primarily by a capillary pressure, in the channel Embodiment 25 is the method of any one of embodiments 13-24, further comprising solidifying the conductive liquid to form an electrically conductive trace in the channel to electrically connect the first and second electrical contacts, while electrically isolated from the underneath electrical circuitry.
Embodiment 26 is the method of any one of embodiments 15-25, further comprising forming a footprint of the standoff onto the curable material when pressing the stamp against the curable material.

Reference throughout this specification to “one embodiment,” “certain embodiments,” “one or more embodiments” or “an embodiment,” whether or not including the term “exemplary” preceding the term “embodiment,” means that a particular feature, structure, material, or characteristic described in connection with the embodiment is included in at least one embodiment of the certain exemplary embodiments of the present disclosure. Thus, the appearances of the phrases such as “in one or more embodiments,” “in certain embodiments,” “in one embodiment” or “in an embodiment” in various places throughout this specification are not necessarily referring to the same embodiment of the certain exemplary embodiments of the present disclosure. Furthermore, the particular features, structures, materials, or characteristics may be combined in any suitable manner in one or more embodiments.

While the specification has described in detail certain exemplary embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. In particular, as used herein, the recitation of numerical ranges by endpoints is intended to include all numbers subsumed within that range (e.g., 1 to 5 includes 1, 1.5, 2, 2.75, 3, 3.80, 4, and 5). In addition, all numbers used herein are assumed to be modified by the term “about.” Furthermore, all publications and patents referenced herein are incorporated by reference in their entirety to the same extent as if each individual publication or patent was specifically and individually indicated to be incorporated by reference. Various exemplary embodiments have been described. These and other embodiments are within the scope of the following claims.

1. An electrical device comprising:
a substrate having a major surface;
an electrical circuitry provided on the major surface of the substrate, the electrical circuitry comprising a first electrical contact and a second electrical contact separated by a portion of the electrical circuitry; and
an electrical jumper passing over at least a portion of the electrical circuitry and electrically connecting the first and second electrical contacts,
wherein the electrical jumper comprises an insulating layer disposed on the major surface of the substrate and covering at least a portion of the electrical circuitry, at least one channel is formed onto the insulating layer, and an electrically conductive trace is formed in the channel to electrically connect the first and second electrical contacts, while electrically isolated from the underneath electrical circuitry.

2. The electrical device of claim 1, wherein the insulating layer is a product of curing a curable liquid.

3. The electrical device of claim 1, wherein the insulating layer further comprises first and second reservoirs, and the at least one channel fluidly connects the first and second reservoirs.

4. The electrical device of claim 1, wherein the first and second reservoirs are through holes such that the electrically conductive trace electrically connects to the first and second electrical contacts through the first and second reservoirs, respectively.

5. The electrical device of claim 1, wherein the electrical circuitry includes an antenna.

6. A method of making an electrical device comprising:
providing a substrate having a major surface, an electrical circuitry provided on the major surface of the substrate, the electrical circuitry comprising first and second electrical contacts separated by a portion of the electrical circuitry;
providing a layer of curable material to cover at least a portion of the electrical circuitry on the major surface of the substrate;
pressing a micro-replication stamp against the layer of curable material to create one or more patterned features thereon;
solidifying the curable material to form an insulating layer having at least one channel thereon; and
disposing a conductive liquid into the channel to form a conductive trace connecting to the first and second electrical contacts of the electrical circuitry.

7. The method of claim 6, wherein the micro-replication stamp has micro-replicated features on a major surface thereof to be in contact with the layer of curable material.

8. The method of claim 7, wherein the micro-replication stamp has a standoff projecting from the major surface thereof, the standoff is located at least partially around a periphery of the micro-replication stamp.

9. The method of claim 8, wherein the standoff has a height no less than that of the micro-replicated features.

10. The method of claim 6, wherein the patterned features include first and second reservoirs and at least one channel fluidly connecting the first and second reservoirs.

11. The method of claim 10, further comprising etching the first and second reservoirs to form through holes to access to the underlying first and second electrical contacts, respectively.

12. The method of claim 6, wherein the micro-replication stamp includes one or more compressible material including polydimethylsiloxane (PDMS) PDMS.

13. The method of claim 6, wherein the conductive liquid includes an ink composition containing electrically conductive particles.

14. The method of claim 6, wherein disposing the conductive liquid into the channel comprises flowing the conductive liquid, primarily by a capillary pressure, in the channel.

15. The method of claim 6, further comprising solidifying the conductive liquid to form an electrically conductive trace in the channel to electrically connect the first and second electrical contacts, while electrically isolated from the underneath electrical circuitry.

16. A micro-replication stamp comprising:
one or more micro-replicated features formed on a major surface thereof; and
a standoff projecting from the major surface thereof, the standoff being located at least partially around a periphery of the stamp,
wherein the standoff has a height no less than that of the micro-replicated features.

17. The stamp of claim 16, wherein the micro-replicated features include at least one channel feature in negative relief.

18. The stamp of claim 17, wherein the micro-replicated features further include first and second reservoir features in negative relief connected by the at least one channel feature in negative relief.

19. The stamp of claim 18, wherein the first and second reservoir features in negative relief each have a height greater than that of the at least one channel feature in negative relief.

20. The stamp of claim 16, wherein the major surface thereof includes one or more compressible material including polydimethylsiloxane (PDMS).
